(19) United States
(12) Patent Application Publication
(10) Pub. No.: US 2026/0299028 A1
(43) Pub. Date: Oct. 1, 2026

(54) APPARATUS AND METHOD FOR ESTIMATING A STATE OF CHARGE OF A BATTERY

(71) Applicants: HYUNDAI MOTOR COMPANY, Seoul (KR); KIA CORPORATION, Seoul (KR); The Industry & Academic Cooperation in Chungnam National University (IAC), Daejeon (KR)

(72) Inventors: Cheol Beom Lim, Hwaseong-si (KR); Jong Hoon Kim, Daejeon (KR)

(73) Assignees: HYUNDAI MOTOR COMPANY, Seoul (KR); KIA CORPORATION, Seoul (KR); The Industry & Academic Cooperation in Chungnam National University (IAC), Daejeon (KR)

(21) Appl. No.: 19/311,512

(22) Filed: Aug. 27, 2025

(30) Foreign Application Priority Data
Mar. 31, 2025 (KR) 10-2025-0041733

(51) Int. Cl. G01R 31/367; G01R 31/3842; G01R 31/389; H01M 10/48

(52) U.S. Cl. CPC G01R 31/367; G01R 31/3842; G01R 31/389; H01M 10/48

(57) ABSTRACT

A battery state of charge (SOC) estimation apparatus includes a memory configured to store at least one instruction and at least one processor configured, by executing the at least one instruction to obtain a measured terminal voltage and a measured charge and discharge current of the battery. The at least one processor may further generate a fusion model including a plurality of equivalent circuit models for outputting estimated values of different terminal voltages based on the measured terminal voltage and the measured charge and discharge current. The at least one processor may estimate the SOC of the battery based on an output of the fusion model.

### CROSS-REFERENCE TO RELATED APPLICATION

This application claims the benefit of and priority to Korean Patent Application No. 10-2025-0041733, filed in the Korean Intellectual Property Office on Mar. 31, 2025, the entire contents of which are incorporated herein by reference.

### TECHNICAL FIELD

The present disclosure relates to an apparatus and a method for estimating a state of charge (SOC) of a battery.

### BACKGROUND

In general, an electric vehicle drives with electric energy as power and includes a battery having a plurality of battery cells configured to store electric energy. Such a battery cell converts chemical energy into electrical energy to supply the electrical energy (discharging) or converts electrical energy supplied from the outside into chemical energy to store the chemical energy (charging).

To prevent over-charging and over-discharging of the battery, a charge current and a discharge current of the battery should be adjusted according to a state of charge (SOC) of the battery. However, the SOC of the battery is unable to be directly measured but is estimated based on the terminal voltage of the battery and the current of the battery. Thus, to more safely and efficiently control the battery, it is the most important to accurately estimate the SOC of the battery. In general, Kalman filter-based estimation is frequently used to estimate an SOC of the battery and a process of estimating a terminal voltage of the battery based on an equivalent circuit model may be included in the Kalman filter. For accurate estimation, there is a need for a battery modeling technology capable of sufficiently reflecting an electrochemical reaction in the battery.

The subject matter described in this background section is intended to promote an understanding of the background of the disclosure and thus may include subject matter that is not already known to those of ordinary skill in the art. The statements in this section merely provide background information related to the present disclosure and may not constitute prior art.

### SUMMARY

The present disclosure has been made to solve the above-mentioned problems occurring in the prior art while advantages achieved by the prior art are maintained intact.

The present disclosure relates to an apparatus for estimating a state of charge (SOC) of a battery at high accuracy and a method thereof.

The technical problems to be solved by the present disclosure are not limited to the aforementioned problems. Any other technical problems not mentioned herein should be clearly understood from the following description by those having ordinary skill in the art to which the present disclosure pertains.

According to an aspect of the present disclosure, an apparatus for estimating a state of charge (SOC) of a battery may include a memory configured to store at least one instruction and at least one processor configured, by executing the at least one instruction, to obtain a measured terminal voltage and a measured charge and discharge current of the battery. The at least one processor may further generate a fusion model including a plurality of equivalent circuit models for outputting estimated values of different terminal voltages based on the measured terminal voltage and the measured charge and discharge current. The at least one processor may further determine the SOC of the battery based on an output of the fusion model.

According to an embodiment, the fusion model may include at least one of a first equivalent circuit model for simulating a change in open circuit voltage (OCV) of the battery, a second equivalent circuit model for simulating a voltage change corresponding to a direct current of the battery, or a third equivalent circuit model for simulating a voltage change corresponding to an alternating current of the battery.

According to an embodiment, the at least one processor may further extract a first data area associated with an OCV of the battery, a second data area associated with a high-frequency component, and a third data area associated with a low-frequency component, based on the measured terminal voltage and the measured charge and discharge current of the battery.

According to an embodiment, the at least one processor may further extract a parameter of an equivalent circuit model, among the plurality of equivalent circuit models, corresponding to any one of the first data area, the second data area, or the third data area.

According to an embodiment, the at least one processor may further extract the second data area and the third data area via performing discrete wavelet transform (DWT) for the measured terminal voltage and the measured charge and discharge current of the battery.

According to an embodiment, the at least one processor may further obtain impedance data of the battery based on electrochemical impedance spectroscopy (EIS. The at least one processor may further extract the parameter of the equivalent circuit model for simulating a voltage change corresponding to an alternating current of the battery based on the impedance data.

According to an embodiment, the at least one processor may further obtain impedance of the battery for each frequency via performing short-time Fourier transform (STFT) for the measured terminal voltage and the measured charge and discharge current of the battery. The at least one processor may further obtain the impedance data based on the impedance of the battery for each frequency.

According to an embodiment, the at least one processor may further set weights for estimated terminal voltages output from each of the plurality of equivalent circuit models. The at least one processor may further obtain a fusion estimation value of a terminal voltage based on the weight. The at least one processor may estimate the SOC of the battery based on the fusion estimation value.

According to an embodiment, the at least one processor may further obtain a first estimated value in which the fusion estimation value of the terminal voltage is corrected using the measured terminal voltage.

According to an embodiment, the at least one processor may further obtain a second estimated value for the terminal voltage based on Ah-counting. The at least one processor may further determine whether the SOC of the battery is normal, based on a difference between the first estimated value and the second estimated value and a predetermined threshold.

According to another aspect of the present disclosure, a method for estimating a state of charge (SOC) of a battery may include obtaining a measured terminal voltage and a measured charge and discharge current of the battery. The method may further include generating a fusion model including a plurality of equivalent circuit models for outputting estimated values of different terminal voltages based on the measured terminal voltage and the measured charge and discharge current. The method may further include determining the SOC of the battery based on an output of the fusion model.

According to an embodiment, the fusion model may include at least one of a first equivalent circuit model for simulating a change in open circuit voltage (OCV) of the battery, a second equivalent circuit model for simulating a voltage change corresponding to a direct current of the battery, or a third equivalent circuit model for simulating a voltage change corresponding to an alternating current of the battery.

According to an embodiment, the method may further include extracting a first data area associated with an OCV of the battery, a second data area associated with a high-frequency component, and a third data area associated with a low-frequency component, based on the measured terminal voltage of the battery and the measured charge and discharge current of the battery.

According to an embodiment, the method may further include extracting a parameter of an equivalent circuit model, among the plurality of equivalent circuit models, corresponding to any one of the first data area, the second data area, or the third data area.

According to an embodiment, extracting may include extracting the second data area and the third data area via performing discrete wavelet transform (DWT) for the measured terminal voltage and the measured charge and discharge current of the battery.

According to an embodiment, extracting the parameter may include obtaining impedance data of the battery based on electrochemical impedance spectroscopy (EIS). Extracting the parameter may further include extracting the parameter of the equivalent circuit model for simulating a voltage change corresponding to an alternating current of the battery based on the impedance data.

According to an embodiment, obtaining the impedance data may include obtaining impedance of the battery for each frequency via performing short-time Fourier transform (STFT) for the measured terminal voltage and the measured charge and discharge current of the battery. Obtaining the impedance data may further include obtaining the impedance data based on the impedance of the battery for each frequency.

According to an embodiment, determining may include setting weights for estimated terminal voltages output from each of the plurality of equivalent circuit models. Determining may further include obtaining a fusion estimation value of a terminal voltage based on the weights. Determining may further include estimating the SOC of the battery based on the fusion estimation value.

According to an embodiment, obtaining the fusion estimation value may include obtaining a first estimated value in which the fusion estimation value of the terminal voltage is corrected using the measured terminal voltage.

According to an embodiment, the method may further include obtaining a second estimated value for the terminal voltage based on Ah-counting. The method may further include determining whether the SOC of the battery is normal, based on a difference between the first estimated value and the second estimated value and a predetermined threshold.

### BRIEF DESCRIPTION OF THE DRAWINGS

The above and other objects, features, and advantages of the present disclosure should be more apparent from the following detailed description taken in conjunction with the accompanying drawings:

FIG. 1 is a block diagram illustrating an example of an internal configuration of an apparatus for estimating a state of charge (SOC) of a battery according to an embodiment of the present disclosure;

FIG. 2 is a drawing illustrating an example of a measured voltage and a measured current according to an embodiment of the present disclosure;

FIG. 3 is a drawing for describing a method for generating a fusion model according to an embodiment of the present disclosure;

FIG. 4 is a drawing for describing an example of data conversion according to an embodiment of the present disclosure;

FIG. 5 is a drawing for describing another example of data conversion according to an embodiment of the present disclosure;

FIG. 6 is a drawing for describing an example of an equivalent circuit model according to an embodiment of the present disclosure;

FIG. 7 is a drawing for describing an example of impedance data according to an embodiment of the present disclosure;

FIG. 8 is a drawing for describing a process of obtaining an estimated value of an SOC of a battery according to an embodiment of the present disclosure;

FIG. 9 is a drawing for describing a process of evaluating an estimated value of an SOC of a battery according to an embodiment of the present disclosure;

FIG. 10 is a flowchart for describing an example of a method for estimating a state of charge (SOC) of a battery according to an embodiment of the present disclosure; and

FIG. 11 is a drawing for describing an example of a computing system associated with a battery SOC estimation apparatus or a battery SOC estimation method according to an embodiment of the present disclosure.

### DETAILED DESCRIPTION

Hereinafter, some embodiments of the present disclosure are described in detail with reference to the drawings. In adding the reference numerals to the components of each drawing, it should be noted that the identical or equivalent components are designated by the identical numerals even when the components are displayed on other drawings. Further, in describing the embodiment of the present disclosure, a detailed description of well-known features or functions has been omitted in order not to unnecessarily obscure the gist of the present disclosure.

In describing components of embodiments of the present disclosure, the terms first, second, A, B, (a), (b), and the like may be used herein. These terms are only used to distinguish one component from another component and do not limit the corresponding components to the order or priority of the corresponding components. Furthermore, unless otherwise defined, all terms including technical and scientific terms used herein have the same meaning as being generally understood by those having ordinary skill in the art to which the present disclosure pertains. Such terms as those defined in a generally used dictionary should be interpreted as having meanings equal to the contextual meanings in the relevant field of art and should not be interpreted as having ideal or excessively formal meanings unless clearly defined as having such in the present application.

Furthermore, in the present disclosure, the expression “greater than” or “less than” is used to determine whether a specific condition is satisfied or fulfilled, is only to represent an example, and does not exclude the expression “greater than or equal to” or “less than or equal to”. A condition described as being “greater than or equal to” may be replaced with a condition described as being “greater than”, a condition describing as being “less than or equal to” may be replaced with a condition described as being “less than”, and a condition described as being “greater than or equal to and less than” may be replaced with “greater than and less than or equal to”. Furthermore, hereinafter, “A” and “B” refer to at least one of components from A (including A) to B (including B). When a controller, module, component, device, element, or the like of the present disclosure is described as having a purpose or performing an operation, function, or the like, the controller, module, component, device, element, or the like should be considered herein as being “configured to” meet that purpose or to perform that operation or function. Each controller, module, component, device, element, and the like may separately embody or be included with a processor and a memory, such as a non-transitory computer readable media, as part of the apparatus. In the present disclosure, each of phrases such as “A or B”, “at least one of A and B”, “at least one of A or B”, “A, B or C”, “at least one of A, B and C”, “at least one of A, B or C” and “at least one of A, B, or C, or a combination thereof” are intended to encompass any one of the listed elements and any combination of two or more of the listed elements, unless otherwise explicitly stated.

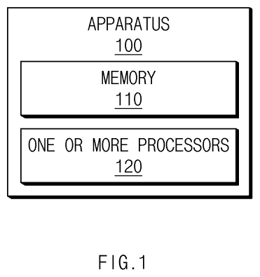

Hereinafter, embodiments of the present disclosure are described in detail with reference to FIGS. 1-11.

FIG. 1 is a block diagram illustrating an example of an internal configuration of an apparatus for estimating a state of charge (SOC) of a battery according to an embodiment of the present disclosure.

Referring to FIG. 1, an apparatus 100 for estimating a state of charge (SOC) of a battery may include a memory 110 and one or more processors 120. The memory 110 may store at least one instruction. The one or more processors 120 may execute the at least one instruction.

According to an embodiment, the apparatus 100 may be included in a battery management system (BMS) or may be configured as a system different from the BMS.

According to an embodiment, the apparatus 100 may be included in a battery pack configured to include a battery unit, a sensor device, and the BMS. For example, the battery unit may refer to a component, which is electrically connected to a target device to supply power. Herein, the target device may include an electrical, electronic, or mechanic device for operating by receiving power from the battery pack. For example, the target device may be, but is not limited to, an electric vehicle (EV). According to an embodiment, the battery unit may be a battery cell or a battery bank. For example, the battery cell may be, but is not limited to, a lithium-ion (Li-ion) battery, a lithium-ion (Li-ion) polymer battery, a nickel cadmium (Ni—Cd) battery, a nickel hydrogen (Ni—MH) battery, or the like. The sensor device may refer to a component for obtaining values associated with the state of the battery unit. For example, the values associated with the state of the battery unit may include one or more values for a voltage, a current, resistance, a state of charge (SOC), a state of health (SOH), or a temperature, or any combination thereof. The BMS may refer to a component for controlling or managing the battery pack. According to an embodiment, the operation of the apparatus 100 below may be performed by the BMS.

According to an embodiment, the apparatus 100 may be configured as another device outside the battery pack. For example, the apparatus 100 may be configured to be included in various devices, such as a server, a cloud, a charger, or a charger/discharger outside the battery pack. According to an embodiment, the apparatus 100 may be connected to the battery pack in a wireless or wired communication scheme to transmit and receive information. According to an embodiment, the operation of the apparatus 100 below may be performed by the various devices, such as the server, the cloud, the charger, or the charger/discharger.

Meanwhile, the memory 110 may store at least some of pieces of data processed by the apparatus 100.

According to an embodiment, the memory 110 may store a measured terminal voltage of the battery and a measured charge and discharge current of the battery. For example, the memory 110 may store the measured terminal voltage of the battery and the measured charge and discharge current of the battery. The terminal voltage of the battery and the charge and discharge current of the battery are measured in real time.

According to an embodiment, the memory 110 may store a default setting value for a structure of an equivalent circuit model for simulating the battery. For example, the default setting value for the structure of the equivalent circuit model may include one or more resistors and one or more capacitors. Furthermore, in response to that the equivalent circuit model for simulating the battery is determined, the memory 110 may store parameters respectively corresponding to components of the determined equivalent circuit model. For example, the parameters may include an open circuit voltage (OCV) of the battery, ohmic resistance of the battery, a time constant value, a resistance value, a capacity value of a capacitor, an impedance value, and the like. However, the description of the parameters is only an example, and the present disclosure is not limited thereto.

According to an embodiment, the memory 110 may store a certain equation for processing conversion performed by the one or more processors 120. For example, the memory 110 may store an equation for processing wavelet transform and short-time Fourier transform, which is described below.

According to an embodiment, the memory 110 may store data including an SOC according to the OCV of the battery. For example, the data including the SOC according to the OCV may be data obtained via an experiment performed in advance.

According to an embodiment, the memory 110 may store a weight assigned to each of a plurality of equivalent circuit models included in a fusion model, which is described below. In detail, the memory 110 may store a weight assigned to each of estimated values of the terminal voltage of the battery, which are output by the plurality of equivalent circuit models.

According to an embodiment, the one or more processors 120 may estimate an SOC of the battery based on a measured terminal voltage of the battery and a measured charge and discharge current of the battery. According to an embodiment, the one or more processors 120 may estimate the SOC of the battery based on an output of the fusion model including the plurality of equivalent circuit models. According to an embodiment, each of the plurality of equivalent circuit models may output a different estimated value of the terminal voltage based on the measured terminal voltage of the battery and the measured charge and discharge current of the battery.

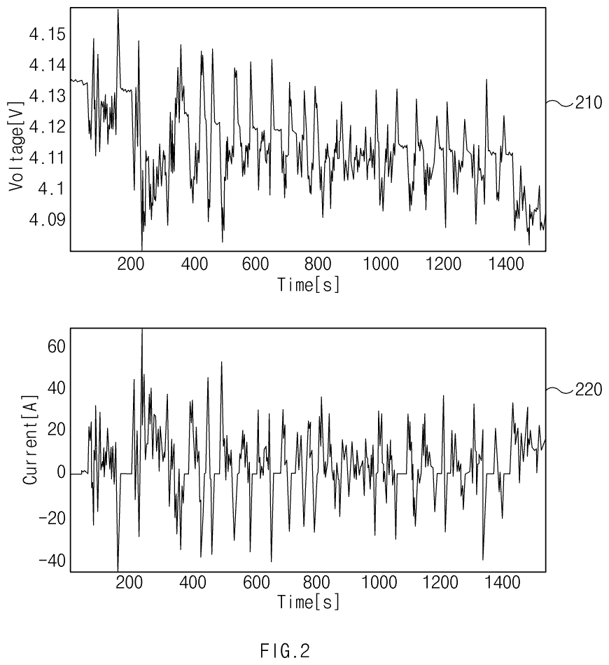

Hereinafter, operations respectively performed by the components included in the apparatus 100 shown in FIG. 1 are described in detail with reference to FIGS. 2-9.

FIG. 2 is a drawing illustrating an example of a measured voltage and a measured current according to an embodiment of the present disclosure.

Referring to FIG. 2, one or more processors 120 may obtain a measured value 210 of a terminal voltage of a battery and a measured value 220 of a charge and discharge current of the battery.

According to an embodiment, the battery may include a battery connected to an electric vehicle (EV). According to an embodiment, the measured value 210 of the terminal voltage of the battery and the measured value 220 of the charge and discharge current of the battery may be values measured while the EV is operating. According to an embodiment, the measured value 210 of the terminal voltage of the battery and the measured value 220 of the charge and discharge current of the battery may be values measured while the EV is driving or measured while the EV is stopping.

According to an embodiment, the measured value 210 of the terminal voltage of the battery and the measured value 220 of the charge and discharge current of the battery may be collected by a battery management system (BMS). For example, the BMS may be installed in the EV. For example, the BMS may monitor a state of the battery in real time and may collect the measured value 210 of the terminal voltage of the battery and the measured value 220 of the charge and discharge current of the battery in real time using a voltage sensor or a current sensor. For example, the one or more processors 120 may be connected to the BMS in a wireless or wired communication scheme to obtain the measured value 210 of the terminal voltage of the battery and the measured value 220 of the charge and discharge current of the battery, which are collected in real time.

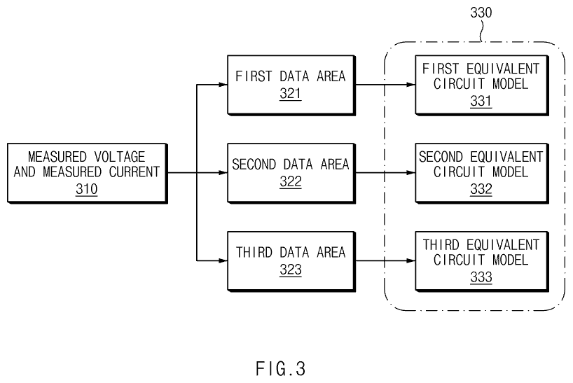

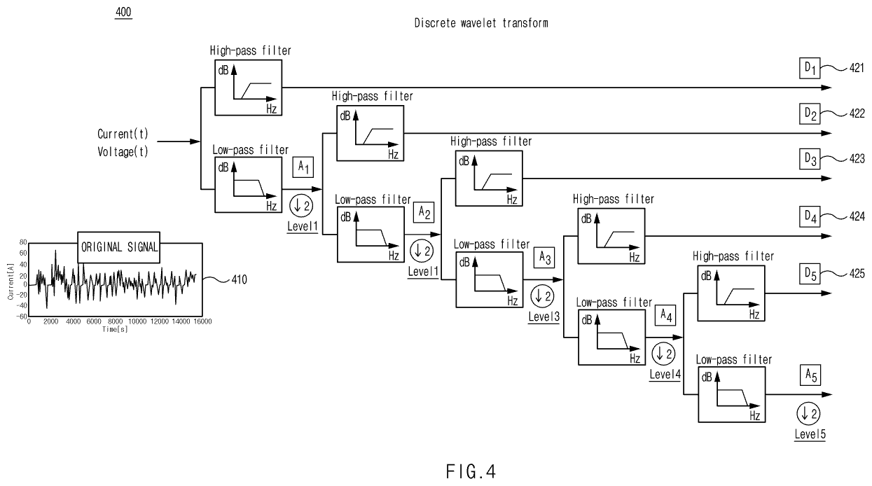

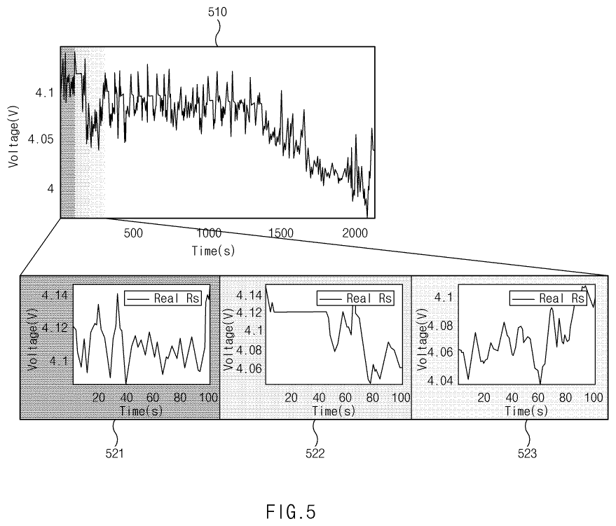

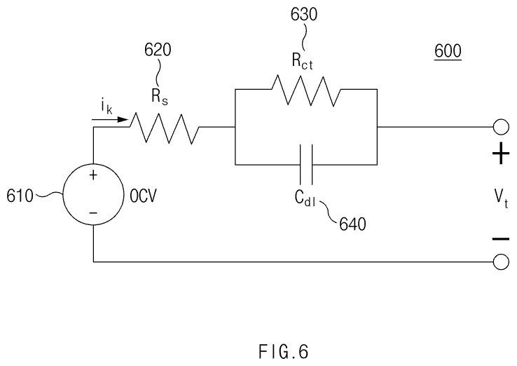

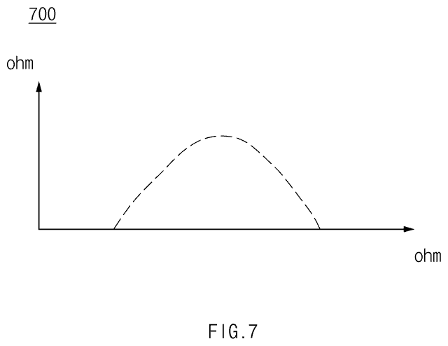

FIG. 3 is a drawing for describing a method for generating a fusion model according to an embodiment of the present disclosure. FIG. 4 is a drawing for describing an example of data conversion according to an embodiment of the present disclosure. FIG. 5 is a drawing for describing another example of data conversion according to an embodiment of the present disclosure. FIG. 6 is a drawing for describing an example of an equivalent circuit model according to an embodiment of the present disclosure. FIG. 7 is a drawing for describing an example of impedance data according to an embodiment of the present disclosure.

Referring to FIG. 3, one or more processors 120 may generate a fusion model 330 including a plurality of equivalent circuit models 331, 332, and 333 for outputting estimated values of different terminal voltages based on a measured value 310 of a terminal voltage and a measured value 310 of a charge and discharge current.

According to an embodiment, the one or more processors 120 may individually generate the equivalent circuit models 331, 332, and 333 included in the fusion model 330 based on the measured value 310 of the terminal voltage and the measured value 310 of the charge and discharge current. According to an embodiment, the one or more processors 120 may generate the first equivalent circuit model 331, the second equivalent circuit model 332, and the third equivalent circuit model 333 sequentially or in parallel.

According to an embodiment, the first equivalent circuit model 331, the second equivalent circuit model 332, and the third equivalent circuit model 333 included in the fusion model 330 may correspond to different data areas 321, 322, and 323, respectively. In detail, the first equivalent circuit model 331, the second equivalent circuit model 332, and the third equivalent circuit model 333 may be models for simulating an operation of the battery in the different data areas 321, 322, and 323, respectively. Herein, the operation of the battery may include a change in voltage of the battery. According to an embodiment, the one or more processors 120 may extract a parameter of an equivalent circuit model corresponding to any one of the first data area 321, the second data area 322, and the third data area 323, using the any one of the first data area 321, the second data area 322, or the third data area 323.

According to an embodiment, the first equivalent circuit model 331 may be a model for simulating a change in open circuit voltage (OCV) of the battery. For example, the first equivalent circuit model 331 may correspond to the first data area 321 associated with the OCV of the battery. In an embodiment, the one or more processors 120 may extract the first data area 321 based on the measured value 310 of the terminal voltage and the measured value 310 of the charge and discharge current. For example, the one or more processors 120 may determine a stable state of the battery and may extract the first data area 321 including a measured voltage corresponding to the stable state of the battery. According to an embodiment, the stable state of the battery may refer to a state of the battery, which is not connected to a load, after a certain time, may refer to a state rather than a charge and discharge state, or may refer to a state in which current does not flow. According to an embodiment, the one or more processors 120 may extract the first data area 321 based on various schemes for extracting an OCV of the battery.

According to an embodiment, the one or more processors 120 may generate the first equivalent circuit model 331 based on the extracted first data area 321. According to an embodiment, the one or more processors 120 may extract a parameter of the first equivalent circuit model 331 using certain data included in the first data area 321. For example, the one or more processors 120 may extract one or more parameters (e.g., a resistance value, a capacity value of a capacitor, a time constant value, or the like) constituting the first equivalent circuit model 331, using OCV data of the battery, which is included in the first data area 321.

According to an embodiment, the second equivalent circuit model 332 may be a model for simulating a voltage change corresponding to a direct current of the battery. According to an embodiment, the second equivalent circuit model 332 may correspond to the second data area 322 associated with a high-frequency component of the measured value 310 of the terminal voltage and the measured value 310 of the charge and discharge current or may correspond to the third data area 323 associated with a low-frequency component of the measured value 310 of the terminal voltage and the measured value 310 of the charge and discharge current.

According to an embodiment, the third equivalent circuit model 333 may be a model for simulating a voltage change corresponding to an alternating current of the battery. According to an embodiment, the third equivalent circuit model 333 may correspond to the third data area 323 associated with the low-frequency component of the measured value 310 of the terminal voltage and the measured value 310 of the charge and discharge current or may correspond to the second data area 322 associated with of the high-frequency component of the measured value 310 of the terminal voltage and the measured value 310 of the charge and discharge current.

According to an embodiment, the one or more processors 120 may extract the second data area 322 and/or the third data area 323 based on the measured value 310 of the terminal voltage and the measured value 310 of the charge and discharge current. For example, the one or more processors 120 may extract the second data area 322 and/or the third data area 323 via converting the measured value 310 of the terminal voltage and the measured value 310 of the charge and discharge current into a frequency domain.

According to an embodiment, the one or more processors 120 may extract the second data area 322 and/or the third data area 323 by performing discrete wavelet transform (DWT) for the measured value 310 of the terminal voltage and/or the measured value 310 of the charge and discharge current. Wavelet transform has an advantage capable of adjusting time-frequency resolution to simultaneously analyze data in a time domain and a frequency domain. The DWT has an advantage capable of analyzing data (e.g., real-time voltage data or current data) in real time because the amount of calculation is smaller than continuous wavelet transform.

Referring to FIG. 4, the result 400 of DWT for the measured value 310 of the terminal voltage and/or the measured value 310 of the charge and discharge current is illustrated. According to an embodiment, the one or more processors 120 may perform wavelet transform at a certain time period or a specific time position. According to an embodiment, the one or more processors 120 may repeatedly perform a process of dividing the measured value 310 of the terminal voltage and/or the measured value 310 of the charge and discharge current into a low-frequency component and a high-frequency component to decompose the measured value 310 of the terminal voltage and/or the measured value 310 of the charge and discharge current into a plurality of frequency bands. For example, the one or more processors 120 may divide the measured value 310 of the terminal voltage and/or the measured value 310 of the charge and discharge current into a first low-frequency component and a first high-frequency component using a certain filter (e.g., a low-frequency filter and a high-frequency filter). The one or more processors 120 may divide the first low-frequency component into a second low-frequency component and a second high-frequency component again. Furthermore, the one or more processors 120 may divide the second low-frequency component into a third low-frequency component and a third high-frequency component again using a certain filter (e.g., a low-frequency filter and a high-frequency filter). For example, referring to FIG. 4, an original signal 410 about the measured value 310 of the terminal voltage and/or the measured value 310 of the charge and discharge current may be decomposed into signals 421-425 corresponding to different levels of frequency bands. For example, the one or more processors 120 may extract the second data area 322 based on signals corresponding to a high-frequency band among the signals 421-425. Furthermore, the one or more processors 120 may extract the third data area 323 based on signals corresponding to a low-frequency band among the signals 421-425.

According to an embodiment, the one or more processors 120 may extract the second data area 322 and/or the third data area 323 via performing short-time Fourier transform (STFT) for the measured value 310 of the terminal voltage and/or the measured value 310 of the charge and discharge current. The STFT has an advantage in which time information is not lost, because of dividing a signal into certain intervals (e.g., windows) and performing conversion for each interval, upon comparison with existing Fourier transform.

Referring to FIG. 5, the example in which the STFT is performed for a measured value 510 of a terminal voltage is illustrated as an example. According to an embodiment, the one or more processors 120 may perform the STFT for the measured value 310 of the terminal voltage and/or the measured value 310 of the charge and discharge current using a certain window, the size (or length) of which is determined in advance. According to an embodiment, the size of the window may be a user setting value and may be changed. As the example shown in FIG. 5, because the measured value 510 of the terminal voltage (or a measured current) is obtained in real time, it may be difficult to extract information of a frequency domain about a long time interval in real time. According to an embodiment, the one or more processors 120 may segment the measured value 510 of the terminal voltage into unit time intervals 521, 522, and 523 and may perform frequency domain transform (e.g., Fourier transform) for each of the unit time intervals 521, 522, and 523. For example, the one or more processors 120 may extract the second data area 322 based on a high-frequency component transformed in each of the unit time intervals 521, 522, and 523. Furthermore, the one or more processors 120 may extract the third data area 323 based on a low-frequency component transformed in each of the unit time intervals 521, 522, and 523.

According to an embodiment, the one or more processors 120 may generate the second equivalent circuit model 332 based on the extracted second data area 322. For example, the one or more processors 120 may extract a parameter of the second equivalent circuit model 332 using certain data included in the second data area 322. For example, the one or more processors 120 may extract one or more parameters (e.g., a resistance value, a capacity value of a capacitor, a time constant value, or the like) constituting the second equivalent circuit model 332, using data of a high-frequency component, which is included in the second data area 322.

According to an embodiment, the one or more processors 120 may generate the third equivalent circuit model 333 based on the extracted third data area 323. For example, the one or more processors 120 may extract a parameter of the third equivalent circuit model 333 using certain data included in the third data area 323. For example, the one or more processors 120 may extract one or more parameters (e.g., a resistance value, a capacitance value, a time constant value, or the like) constituting the third equivalent circuit model 333, using data of a low-frequency component, which is included in the third data area 323.

Meanwhile, referring to FIG. 6, an equivalent circuit model 600 according to an embodiment of the present disclosure is illustrated. For example, the equivalent circuit model 600 may be configured as a 1 Randles (1RC) model. However, the equivalent circuit model 600 shown in FIG. 6 is only an example. The number or types of components (resistors or capacitors) constituting the equivalent circuit model 600 are not limited to the example shown in FIG. 6. For example, the equivalent circuit model 600 may further include an inductor. According to an embodiment, a voltage source 610 of the equivalent circuit model 600 may correspond to an OCV. The equivalent circuit model 600 may include one or more serial resistors 620. The equivalent circuit model 600 may include a parallel RC circuit may include one or more parallel resistors 630 and one or more parallel capacitors 640.

Meanwhile, because some contents of the method for generating the second equivalent circuit model 332 and the method for generating the third equivalent circuit model 333 may be duplicated with each other, they are described below together. Hereinafter, for convenience of description, the equivalent circuit model may refer to the second equivalent circuit model 332 and/or the third equivalent circuit model 333, and the data area may refer to the second data area 322 and/or the third data area 323.

According to an embodiment, the one or more processors 120 may extract a parameter of the equivalent circuit model using certain data included in the data area.

According to an embodiment, the one or more processors 120 may obtain impedance data of the battery in the data area based on electrochemical impedance spectroscopy (EIS). For example, the impedance data may include impedance of the battery for each frequency. For example, referring to an example of impedance data 700 of the battery shown in FIG. 7, impedance of the battery for each frequency may be represented via a Nyquist plot.

According to an embodiment, the one or more processors 120 may extract a parameter of the equivalent circuit model for simulating a voltage change corresponding to an alternating current of the battery based on the impedance data. According to an embodiment, the one or more processors 120 may optimize the parameter of the equivalent circuit model based on the impedance data. For example, the one or more processors 120 may adjust the parameter in the direction of minimizing a difference between the impedance data and the equivalent circuit model using a certain fitting algorithm. For example, nonlinear least squares (NLS), regression analysis, or the like may be used as the fitting algorithm, but the fitting algorithm is not limited thereto.

According to an embodiment, the one or more processors 120 may obtain impedance of the battery for each frequency via performing STFT for the measured terminal voltage of the battery and the measured charge and discharge current of the battery. Furthermore, the one or more processors 120 may obtain impedance data based on the impedance of the battery for each frequency and may extract the parameter of the equivalent circuit model based on the impedance data. According to an embodiment, the one or more processors 120 may obtain the impedance of the battery for each frequency via performing DWT for the measured terminal voltage of the battery and the measured charge and discharge current of the battery.

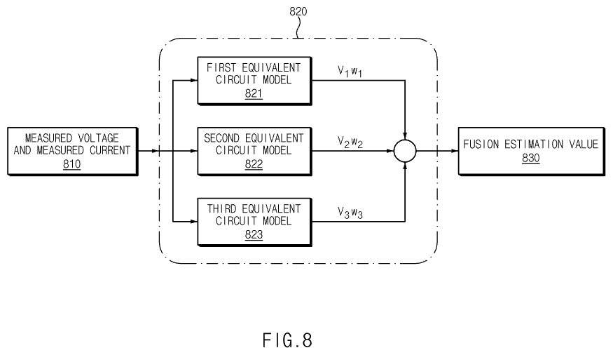

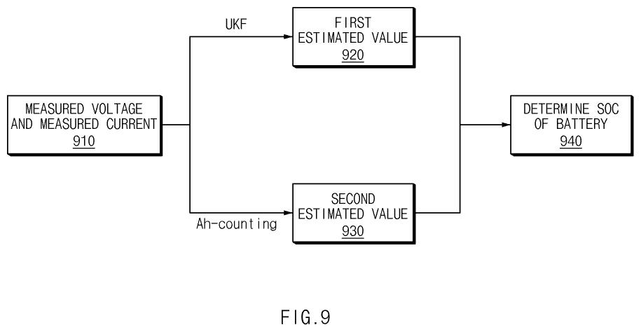

FIG. 8 is a drawing for describing a process of obtaining an estimated value of an SOC of a battery according to an embodiment of the present disclosure. FIG. 9 is a drawing for describing a process of evaluating an estimated value of an SOC of a battery according to an embodiment of the present disclosure.

According to an embodiment, one or more processors 120 may estimate an SOC of a battery based on the output of a fusion model 820. According to an embodiment, the output of the fusion model 820 may be a fusion estimation value 830 for a terminal voltage of the battery.

According to an embodiment, the fusion estimation value 830 may be determined based on the output of each of equivalent circuit models 821, 822, and 823 included in the fusion estimation value 820. According to an embodiment, each of the equivalent circuit models 821, 822, and 823 may output a different estimated value of the terminal voltage based on a measured value 810 of the terminal voltage of the battery and a measured value 810 of a charge and discharge current of the battery.

According to an embodiment, the one or more processors 120 may set a weight for the estimated value of the terminal voltage, which is output by each of the equivalent circuit models 821, 822, and 823. For example, the one or more processors 120 may set a weight for the estimated value of each model based on a certain weight calculation algorithm. According to an embodiment, the weight calculation algorithm may be an algorithm for calculating a weight based on a similarity, relevance, and a conditional probability of the estimated value for the measured terminal voltage.

According to an embodiment, the weight calculation algorithm may be a weight calculation algorithm based on a conditional probability density function. For example, the one or more processors 120 may calculate a probability that the estimated value output by each model will be identical to the measured value, using a conditional probability density function of a Gaussian distribution. Furthermore, the one or more processors 120 may calculate the weight for the estimated value output by each model using the conditional probability density function of each model.

According to an embodiment, the one or more processors 120 may obtain the fusion estimation value 823 of the terminal voltage based on the weight for each of the estimated values of the terminal voltage, which are output by the plurality of the equivalent circuit models 821, 822, and 823. According to an embodiment, the one or more processors 120 may obtain the fusion estimation value 830 about the terminal voltage of the battery using the fusion model 820 to obtain a more accurate estimated value of the terminal voltage of the battery.

Meanwhile, the one or more processors 120 may estimate an SOC of the battery based on the fusion estimation value 830. According to an embodiment, the one or more processors 120 may estimate the SOC of the battery based on a Kalman filter-based SOC estimation method. Herein, the fusion estimation value 830 may be used as one variable in the Kalman filter-based SOC estimation method. For example, the fusion estimation value 830 may be a variable (e.g., a voltage estimation value) used in an output equation.

According to an embodiment, the one or more processors 120 may estimate the SOC of the battery based on an unscented Kalman filter (UKF)-based SOC estimation method. The UKF may be effective for estimation for a non-linear function in that a method for transforming a probability distribution, rather than a linear approximation, is used. For example, the UKF may generate a sigma point in a target function and may perform non-linear transform using the sigma point.

Referring to FIG. 9, the one or more processors 120 may obtain a first estimated value 920 based on a measured value 910 of a terminal voltage of the battery and a measured value 910 of a charge and discharge current of the battery.

Herein, the first estimated value 920 may be an estimated value in which the fusion estimation value 830 of the terminal voltage is corrected using the measured value 910 of the terminal voltage. For example, the one or more processors 120 may perform correction for the fusion estimation value 830 using the above-mentioned UKF. The first estimated value 920 may be an estimated value of the terminal voltage based on the equivalent circuit model, which is corrected based on the UKF.

According to an embodiment, the one or more processors 120 may obtain a second estimated value 930 based on the measured value 910 of the terminal voltage of the battery and the measured value 910 of the charge and discharge current of the battery.

Herein, the second estimated value 930 may be an estimated value in which the terminal voltage is estimated based on Ah-counting or ampere-hour counting. For example, the one or more processors 120 may perform current accumulation based on the measured value 910 of the charge and discharge current. The second estimated value 930 may be an estimated value of the terminal voltage, which is obtained based on the Ah-counting or ampere-hour counting.

According to an embodiment, the one or more processors 120 may determine whether an SOC 940 of the battery is normal, based on a difference between the first estimated value 920 and the second estimated value 930 and a predetermined threshold. For example, when the difference between the first estimated value 920 and the second estimated value 930 is less than the predetermined threshold, the one or more processors 120 may determine that the SOC 940 of the battery is normal. In other words, the one or more processors 120 may determine that the SOC 940 of the battery is normally estimated and the battery is further in a stable state. On the other hand, when the difference between the first estimated value 920 and the second estimated value 930 is greater than or equal to the predetermined threshold, the one or more processors 120 may determine that the SOC 940 of the battery is abnormal. In other words, the one or more processors 120 may determine that the SOC 940 of the battery is abnormally estimated and the battery is further in an abnormal state rather than the stable state.

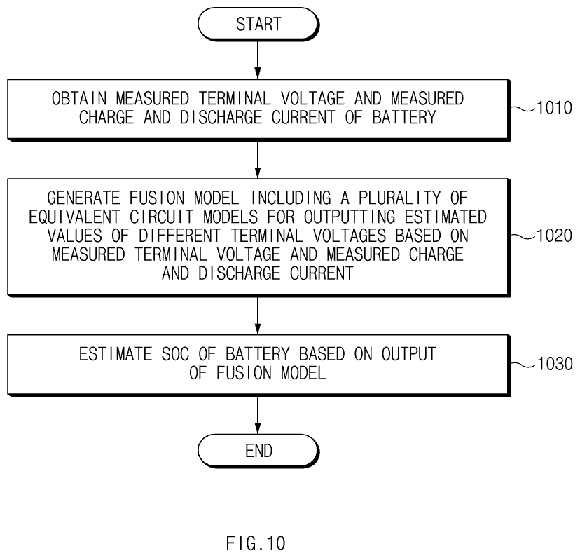

FIG. 10 is a flowchart for describing an example of a method for estimating a state of charge (SOC) of a battery according to an embodiment of the present disclosure.

Referring to FIG. 10, in operation 1010, one or more processors 120 may obtain a measured terminal voltage of a battery and a measured charge and discharge current of the battery.

In operation 1020, the one or more processors 120 may generate a fusion model including a plurality of equivalent circuit models for outputting estimated values of different terminal voltages based on the measured terminal voltage and the measured charge and discharge current.

According to an embodiment, the fusion model may include at least any one of a first equivalent circuit model for simulating a change in OCV of the battery, a second equivalent circuit model for simulating a voltage change corresponding to a direct current of the battery, or a third equivalent circuit model for simulating a voltage change corresponding to an alternating current of the battery.

According to an embodiment, the one or more processors 120 may further extract a first data area associated with an OCV of the battery, a second data area associated with a high-frequency component, and a third data area associated with a low-frequency component, based on the measured terminal voltage of the battery and the measured charge and discharge current of the battery.

According to an embodiment, the one or more processors 120 may further extract a parameter of an equivalent circuit model corresponding to any one of the first data area, the second data area, or the third data area, using the any one of the first data area, the second data area, or the third data area.

According to an embodiment, the one or more processors 120 may extract the second data area and the third data area via performing discrete wavelet transform (DWT) for the measured terminal voltage of the battery and the measured charge and discharge current of the battery.

According to an embodiment, the one or more processors 120 may further obtain impedance data of the battery based on electrochemical impedance spectroscopy (EIS) and extracting the parameter of the equivalent circuit model for simulating a voltage change corresponding to an alternating current of the battery based on the impedance data.

According to an embodiment, the one or more processors 120 may obtain impedance of the battery for each frequency via performing by performing short-time Fourier transform (STFT) for the measured terminal voltage of the battery and the measured charge and discharge current of the battery and obtaining impedance data based on the impedance of the battery for each frequency.

In operation 1030, the one or more processors 120 may estimate an SOC of the battery based on an output of the fusion model.

According to an embodiment, the one or more processors 120 may set a weight for an estimated value of the terminal voltage, which is output by each of the plurality of equivalent circuit models, may obtain a fusion estimation value of the terminal voltage based on the weight, and may estimate the SOC of the battery based on the fusion estimation value.

According to an embodiment, the one or more processors 120 may obtain a first estimated value in which the fusion estimation value of the terminal voltage is corrected using the measured terminal voltage.

According to an embodiment, the one or more processors 120 may further obtain a second estimated value for the terminal voltage based on Ah-counting or ampere-hour counting and determining whether the SOC of the battery is normal, based on a difference between the first estimated value and the second estimated value and a predetermined threshold.

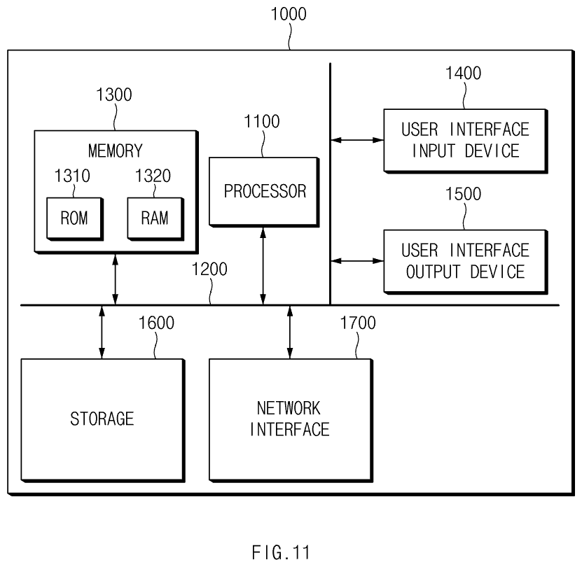

FIG. 11 is a drawing for describing an example of a computing system associated with a battery SOC estimation apparatus or a battery SOC estimation method according to an embodiment of the present disclosure.

Referring to FIG. 11, a computing system 1000 may include at least one processor 1100, a memory 1300, a user interface input device 1400, a user interface output device 1500, a storage 1600, and a network interface 1700, which are connected to each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a read only memory (ROM) 1310 and a random access memory (RAM) 1320.

Thus, the operations of the method or the algorithm described in connection with the embodiments disclosed herein may be embodied directly in hardware or a software module executed by the processor 1100, or in a combination thereof. The software module may reside on a storage medium (i.e., the memory 1300 and/or the storage module 1600) such as a RAM, a flash memory, a ROM, an EPROM, an EEPROM, a register, a hard disc, a removable disk, and a CD-ROM.

The storage medium may be coupled to the processor 1100. The processor 1100 may read out information from the storage medium and may write information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

The battery SOC estimation apparatus and the method thereof according to various embodiments disclosed in the present disclosure may estimate an SOC of a battery at high accuracy.

In addition, various effects ascertained directly or indirectly through the present disclosure may be provided.

Hereinabove, although the present disclosure has been described with reference to embodiments and the accompanying drawings, the present disclosure is not limited thereto but may be variously modified and altered by those having ordinary skill in the art to which the present disclosure pertains without departing from the spirit and scope of the present disclosure claimed in the following claims.

Therefore, embodiments of the present disclosure are not intended to limit the technical spirit of the present disclosure but provided only for the illustrative purpose. The scope of the present disclosure should be construed based on the accompanying claims, and all the technical ideas within the scope equivalent to the claims should be included in the scope of the present disclosure.

What is claimed is:

1. An apparatus for estimating a state of charge (SOC) of a battery, the apparatus comprising:
a memory configured to store at least one instruction; and
at least one processor configured, by executing the at least one instruction, to:
obtain a measured terminal voltage and a measured charge and discharge current of the battery;
generate a fusion model including a plurality of equivalent circuit models for outputting estimated values of different terminal voltages based on the measured terminal voltage and the measured charge and discharge current; and
determine the SOC of the battery based on an output of the fusion model.

2. The apparatus of claim 1, wherein the fusion model includes at least one of a first equivalent circuit model for simulating a change in open circuit voltage (OCV) of the battery, a second equivalent circuit model for simulating a voltage change corresponding to a direct current of the battery, or a third equivalent circuit model for simulating a voltage change corresponding to an alternating current of the battery.

3. The apparatus of claim 1, wherein the at least one processor is configured to:
extract a first data area associated with an OCV of the battery, a second data area associated with a high-frequency component, and a third data area associated with a low-frequency component, based on the measured terminal voltage and the measured charge and discharge current of the battery.

4. The apparatus of claim 3, wherein the at least one processor is configured to:
extract a parameter of an equivalent circuit model, among the plurality of equivalent circuit models, corresponding to any one of the first data area, the second data area, or the third data area.

5. The apparatus of claim 3, wherein the at least one processor is configured to:
extract the second data area and the third data area via performing discrete wavelet transform (DWT) for the measured terminal voltage and the measured charge and discharge current of the battery.

6. The apparatus of claim 4, wherein the at least one processor is configured to:
obtain impedance data of the battery based on electrochemical impedance spectroscopy (EIS); and
extract the parameter of the equivalent circuit model for simulating a voltage change corresponding to an alternating current of the battery based on the impedance data.

7. The apparatus of claim 6, wherein the at least one processor is configured to:
obtain impedance of the battery for each frequency via performing short-time Fourier transform (STFT) for the measured terminal voltage and the measured charge and discharge current of the battery; and
obtain the impedance data based on the impedance of the battery for each frequency.

8. The apparatus of claim 1, wherein the at least one processor is configured to:
set weights for estimated terminal voltages output from each of the plurality of equivalent circuit models;
obtain a fusion estimation value of a terminal voltage based on the weights; and
estimate the SOC of the battery based on the fusion estimation value.

9. The apparatus of claim 8, wherein the at least one processor is configured to:
obtain a first estimated value in which the fusion estimation value of the terminal voltage is corrected using the measured terminal voltage.

10. The apparatus of claim 9, wherein the at least one processor is configured to:
obtain a second estimated value for the terminal voltage based on Ah-counting; and
determine whether the SOC of the battery is normal, based on a difference between the first estimated value and the second estimated value and a predetermined threshold.

11. A method for estimating a state of charge (SOC) of a battery, comprising:
obtaining a measured terminal voltage and a measured charge and discharge current of the battery;
generating a fusion model including a plurality of equivalent circuit models for outputting estimated values of different terminal voltages based on the measured terminal voltage and the measured charge and discharge current; and
determining the SOC of the battery based on an output of the fusion model.

12. The method of claim 11, wherein the fusion model includes at least one of a first equivalent circuit model for simulating a change in open circuit voltage (OCV) of the battery, a second equivalent circuit model for simulating a voltage change corresponding to a direct current of the battery, or a third equivalent circuit model for simulating a voltage change corresponding to an alternating current of the battery.

13. The method of claim 11, further comprising:
extracting a first data area associated with an OCV of the battery, a second data area associated with a high-frequency component, and a third data area associated with a low-frequency component, based on the measured terminal voltage and the measured charge and discharge current of the battery.

14. The method of claim 13, further comprising:
extracting a parameter of an equivalent circuit model, among the plurality of equivalent circuit models, corresponding to any one of the first data area, the second data area, or the third data area.

15. The method of claim 13, wherein extracting includes:
extracting the second data area and the third data area via performing discrete wavelet transform (DWT) for the measured terminal voltage and the measured charge and discharge current of the battery.

16. The method of claim 14, wherein extracting the parameter includes:
obtaining impedance data of the battery based on electrochemical impedance spectroscopy (EIS); and
extracting the parameter of the equivalent circuit model for simulating a voltage change corresponding to an alternating current of the battery based on the impedance data.

17. The method of claim 16, wherein obtaining the impedance data includes:
obtaining impedance of the battery for each frequency via performing short-time Fourier transform (STFT) for the measured terminal voltage and the measured charge and discharge current of the battery; and
obtaining the impedance data based on the impedance of the battery for each frequency.

18. The method of claim 11, wherein determining includes:
setting weights for estimated terminal voltages output from each of the plurality of equivalent circuit models;
obtaining a fusion estimation value of a terminal voltage based on the weights; and
estimating the SOC of the battery based on the fusion estimation value.

19. The method of claim 18, wherein obtaining the fusion estimation value includes:
obtaining a first estimated value in which the fusion estimation value of the terminal voltage is corrected using the measured terminal voltage.

20. The method of claim 19, further comprising:
obtaining a second estimated value for the terminal voltage based on Ah-counting; and
determining whether the SOC of the battery is normal, based on a difference between the first estimated value and the second estimated value and a predetermined threshold.
